(19) United States
(12) Patent Application Publication
(10) Pub. No.: US 2025/0178479 A1
(43) Pub. Date: Jun. 5, 2025

(54) INFORMATION PROCESSING APPARATUS AND INFORMATION PROCESSING METHOD

(71) Applicant: GS Yuasa International Ltd., Kyoto-shi, Kyoto (JP)

(72) Inventor: Yuki IMANAKA, Kyoto-shi, Kyoto (JP)

(21) Appl. No.: 18/689,201

(22) PCT Filed: Aug. 23, 2022
(86) PCT No.: PCT/JP2022/031643

§ 371 Date: Feb. 19, 2025

(30) Foreign Application Priority Data
Sep. 24, 2021 (JP) 2021-155656

(51) Int. Cl. B60L 58/16

(52) U.S. Cl. CPC B60L 58/16

(57) ABSTRACT

An information processing apparatus includes: a storage unit that stores history data relating to degradation of each of a plurality of energy storage devices; an acquisition unit that acquires history data relating to degradation of an energy storage device mounted on a vehicle; a similarity calculation unit that calculates similarity between the acquired history data and the stored history data; an estimation unit that estimates a degradation index based on the stored history data which is similar to the acquired history data; and a transmission unit that transmits the estimated degradation index to the vehicle.

### TECHNICAL FIELD

The present invention relates to an information processing apparatus and an information processing method.

### BACKGROUND ART

Conventionally, a lead-acid battery has been used as a power source of a vehicle, but in recent years, a power train of a vehicle has been diversified not only in a gasoline vehicle but also in a hybrid electric vehicle (HEV), a plug-in hybrid electric vehicle (PHEV), or an electric vehicle (EV). For example, a lead-acid battery which is a power source of a vehicle may be replaced with a lithium ion battery.

It is known that a storage battery mounted on a vehicle repeats charging-discharging by traveling of the vehicle, and degradation (for example, capacity degradation) of the storage battery progresses by repeating charging-discharging. As a method for estimating capacity degradation, for example, various methods such as an internal resistance estimation method and an actual capacity estimation method can be considered. Patent Document 1 discloses a method for estimating a degree of degradation of a vehicle storage battery by calculating an internal resistance of the vehicle storage battery.

### PRIOR ART DOCUMENT

### Patent Document

Patent Document 1: JP-A-2013-142561

### SUMMARY OF THE INVENTION

### Problems to be Solved by the Invention

Although it is possible to use individual degradation estimation methods suitable for individual vehicles, a method for commonly estimating degradation of an energy storage device corresponding to various power trains has not been established.

An object of the present invention is to provide an information processing apparatus and an information processing method capable of commonly estimating degradation of an energy storage device for diversified vehicle systems.

### Means for Solving the Problems

An information processing apparatus according to one aspect of the present invention includes: a storage unit that stores history data relating to degradation of each of a plurality of energy storage devices; an acquisition unit that acquires history data relating to degradation of an energy storage device mounted on a vehicle; a similarity calculation unit that calculates similarity between the acquired history data and the stored history data; an estimation unit that estimates a degradation index based on the stored history data which is similar to the acquired history data; and a transmission unit that transmits the estimated degradation index to the vehicle.

### Advantages of the Invention

According to the present invention, it is possible to commonly estimate the degradation of the energy storage device for diversified vehicle systems.

### BRIEF DESCRIPTION OF THE DRAWINGS

FIG. 1 is a diagram showing a configuration of an information processing system.

FIG. 2 is a diagram showing a configuration of a server.

FIG. 3 is a diagram showing a configuration of an energy storage device DB.

FIG. 4 is a diagram showing an example of time-series data of temperature.

FIG. 5 is a diagram showing an example of a temperature histogram.

FIG. 6 is a diagram showing a calculation example of similarity using a temperature history.

FIG. 7 is a diagram showing an example of a time-series data of an SOC.

FIG. 8 is a diagram showing an example of time-series data of an SOC and a charge-discharge current.

FIG. 9 is a diagram showing an example of weighting calculation.

FIG. 10 is a diagram showing an example of a configuration of a learning model.

FIG. 11 is a diagram showing an example of a configuration of a learning model.

FIG. 12 is a diagram showing an example of estimation of a degradation index by an estimation unit.

FIG. 13 is a flowchart showing a processing procedure of a server.

### MODE FOR CARRYING OUT THE INVENTION

(1) An information processing apparatus includes: a storage unit that stores history data relating to degradation of each of a plurality of energy storage devices; an acquisition unit that acquires history data relating to degradation of an energy storage device mounted on a vehicle; a similarity calculation unit that calculates similarity between the acquired history data and the stored history data; an estimation unit that estimates a degradation index based on the stored history data which is similar to the acquired history data; and a transmission unit that transmits the estimated degradation index to the vehicle.

(12) An information processing method includes: storing history data relating to degradation of each of a plurality of energy storage devices in a storage unit; acquiring history data relating to degradation of an energy storage device mounted on a vehicle; calculating similarity between the acquired history data and the stored history data; estimating a degradation index based on the stored history data which is similar to the acquired history data; and transmitting the estimated degradation index to the vehicle.

The storage unit stores the history data relating to the degradation of each of the plurality of energy storage devices. The history data may be any data relating to the degradation of the energy storage device, and includes, for example, a temperature history, a charge-discharge history, an SOC history, and the like. The history data may be time series data such as temperature, charging-discharging, and SOC, or may be statistical data calculated based on the time series data. For example, the temperature may be time-series data of the temperature, or may be statistical data representing the use time for each section by dividing the temperature into sections. The same applies to charging-discharging and SOC. The history data of the energy storage device of the vehicle is collected from the plurality of vehicles, and the storage unit stores the collected history data in association with each vehicle (or battery management system (BMS)). History data collected at different timings from the same vehicle may be stored. With the storage unit, big data related to degradation can be constructed.

The acquisition unit acquires the history data relating to the degradation of the energy storage device mounted on the vehicle. The energy storage device mounted on the vehicle is an energy storage device for which a degradation index is to be estimated. The vehicle may use any power train (vehicle system).

The similarity calculation unit calculates similarity between the acquired history data and the stored history data. When the similarity is calculated, the history data to be compared may include at least one of a temperature history, a charge-discharge history, and an SOC history. When the temperature history, the charge-discharge history, or the SOC history can be compared, the similarity can be accurately calculated. For example, each pattern similar to the transition pattern of the temperature during use of the energy storage device for which the degradation index is to be estimated, the charge-discharge pattern (charging period, charging cycle, discharging period, discharging cycle, pause period, etc.), or the transition pattern of the SOC is searched from the history data stored in the storage unit.

The estimation unit estimates the degradation index based on the stored history data similar to the acquired history data. For example, the estimation unit can estimate a decrease (degradation index) in the SOH from the time point t1 to the time point tn based on the transition of the SOC and the transition of the temperature from the time point t1 to the time point tn. The transmission unit transmits the degradation index estimated by the estimation unit to the vehicle.

With the above-described configuration, even when there is a situation where the degradation index of the energy storage device mounted on the vehicle cannot be accurately estimated, the degradation index estimated based on the history data similar to the history data reflecting the use state of the energy storage device can be provided to the vehicle, and the degradation of the energy storage device can be commonly estimated for diversified vehicle systems.

(2) The acquisition unit may acquire reliability of a degradation index of the energy storage device mounted on the vehicle, and the transmission unit may transmit, when reliability of the degradation index estimated by the estimation unit is higher than the reliability acquired by the acquisition unit, the estimated degradation index to the vehicle.

The reliability of the degradation index depends on the compatibility between the power train of the vehicle and the degradation estimation method for the energy storage device of the vehicle. For example, the internal resistance estimation method is considered to have high accuracy in a case where the current at the time of cranking is large, but is considered not to have high accuracy in a case of the energy storage device of a vehicle not equipped with an engine, in a case of an auxiliary battery, or the like. When the reliability of the degradation index estimated by the estimation unit is higher than the reliability of the degradation index of the energy storage device mounted on the vehicle, the degradation index is transmitted to the vehicle, whereby a more accurate degradation index can be provided to the vehicle.

(3) The storage unit may store reliability of a degradation index of each of the plurality of energy storage devices, the information processing apparatus may include: a weighting calculation unit that calculates a weighting based on the calculated similarity and the stored reliability; and a selection unit that selects an energy storage device from among the plurality of energy storage devices based on the calculated weighting, and the estimation unit may estimate a degradation index based on history data of the selected energy storage device.

For example, assuming that the similarity is S and the reliability is R, the weighting W is calculated by W=S×R. The selection unit selects the energy storage device from among the plurality of energy storage devices based on the calculated weighting. For example, an energy storage device having the weighting W equal to or more than a predetermined threshold may be selected. Accordingly, the energy storage device can be selected from among the plurality of energy storage devices stored in the storage unit in consideration of both the similarity of the history data and the reliability of the degradation index. A plurality of energy storage devices may be selected.

Since the estimation unit estimates the degradation index based on the history data of the selected energy storage device, the estimation unit can estimate the degradation index in consideration of both the similarity of the history data and the reliability of the degradation index.

(4) The similarity calculation unit may calculate similarity between the acquired history data and history data of an energy storage device, which has a use voltage in the same range as a use voltage of the energy storage device mounted on the vehicle, among the plurality of energy storage devices stored in the storage unit.

The use voltages in the same range may be divided into, for example, a low voltage such as 12 V and a high voltage such as several hundred V. By limiting to the use voltages in the same range, it is possible to suppress calculation of similarity between energy storage devices having different energy storage device characteristics depending on the level of the use voltage, progress of degradation, and the like. Accordingly, the estimation accuracy of the degradation index can be enhanced.

(5) The similarity calculation unit may calculate similarity between the acquired history data and history data of an energy storage device, which has entirely or partially the same active material as an active material of the energy storage device mounted on the vehicle, among the plurality of energy storage devices stored in the storage unit.

By limiting to energy storage devices having entirely or partially the same active material, it is possible to suppress calculation of similarity between energy storage devices having different energy storage device characteristics depending on the difference in active material, progress of degradation, and the like. Accordingly, the estimation accuracy of the degradation index can be enhanced.

(6) The similarity calculation unit may calculate similarity between the acquired history data and history data of an energy storage device of the same manufacturer as the energy storage device mounted on the vehicle among the plurality of energy storage devices stored in the storage unit.

By limiting to the energy storage devices of the same manufacturer, it is possible to suppress calculation of similarity between energy storage devices having different energy storage device characteristics depending on the difference in manufacturer, progress of degradation, and the like. Accordingly, the estimation accuracy of the degradation index can be enhanced.

(7) The storage unit may store position data relating to a use region of each of the plurality of energy storage devices, the acquisition unit may acquire position data related to a use region of the vehicle, and the similarity calculation unit may calculate similarity between the acquired history data and history data of an energy storage device entirely or partially in the same use region as a use region of the energy storage device mounted on the vehicle among the plurality of energy storage devices stored in the storage unit.

The use region may be, for example, 47 prefectures, may be divided into the Kanto region, the Kinki Region, and the like, or may be divided into urban areas, suburban areas, mountain areas, and the like. By limiting to energy storage devices of vehicles used entirely or partially in the same use region, it is possible to suppress calculation of similarity between energy storage devices having different energy storage device characteristics depending on the difference in use region, progress of degradation, and the like. Accordingly, the estimation accuracy of the degradation index can be enhanced.

(8) The history data may include a use time in each of temperature sections for each of the temperature sections of the energy storage device.

The use time in each of temperature sections for each of the temperature sections of the energy storage device is, for example, a time (frequency) during which the energy storage device is used in each temperature range by dividing the temperature into predetermined sections (for example, 5° C., 10° C., and the like). Depending on the use state of the vehicle, the temperature of the energy storage device may be different, and the influence on the degradation of the energy storage device may also be different. By selecting energy storage devices having similar use temperature patterns, the estimation accuracy of the degradation index can be enhanced.

(9) The history data may include a use time in each of SOC sections for each of the SOC sections of the energy storage device.

The use time in each of SOC sections for each of the SOC sections of the energy storage device is, for example, a time (frequency) during which the energy storage device is used in each SOC range by dividing the SOC into predetermined sections (for example, 10% or the like). The transition of the SOC of the energy storage device may be different depending on the use state of the vehicle and the type of the vehicle (for example, HEV, EV, and the like), and it is considered that the influence on the degradation of the energy storage device is also different. By selecting energy storage devices having similar SOC transition patterns, the estimation accuracy of the degradation index can be enhanced.

(10) The history data may include an accumulated charge-discharge amount in each of SOC sections for each of the SOC sections of the energy storage device.

The accumulated charge-discharge amount in each of SOC sections for each of the SOC sections of the energy storage device is, for example, an accumulated charge-discharge amount (Ah) (frequency) of the energy storage device in each SOC range by dividing the SOC into predetermined sections (for example, 10% or the like). The transition of the SOC of the energy storage device may be different depending on the use state of the vehicle and the type of the vehicle (for example, HEV, EV and the like), and it is considered that the influence on the degradation of the energy storage device is also different. By selecting energy storage devices having similar SOC transition patterns, the estimation accuracy of the degradation index can be enhanced.

(11) The estimation unit may predict future degradation estimation of the energy storage device based on the estimated degradation index or transition of the degradation index, and the transmission unit may transmit the prediction of the degradation estimation to the vehicle.

By predicting the future degradation estimation, it is possible to predict the remaining period until the life of the energy storage device mounted on the vehicle, and to replace the energy storage device before the energy storage device becomes unusable. When the plurality of energy storage devices are mounted on the vehicle, only the energy storage device which is approaching the end of its life can be replaced with a new one, and the life of the energy storage devices as a whole of the vehicle can be extended.

Hereinafter, embodiments of an information processing apparatus and an information processing method will be described with reference to the drawings.

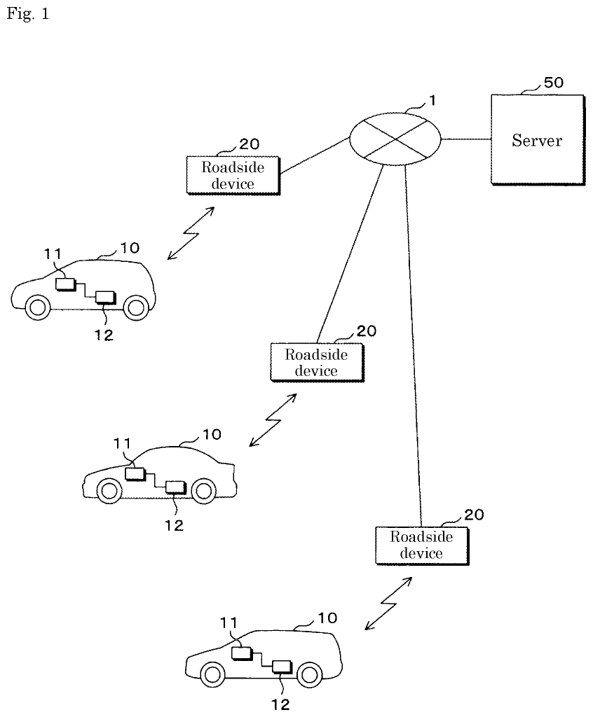

FIG. 1 is a diagram showing a configuration of an information processing system. The information processing system includes a server 50 as an information processing apparatus. The server 50 is connected to a roadside device 20 via a communication network 1. An energy storage device (energy storage device) 11 and a battery management system (BMS) 12 are mounted on a vehicle 10. The energy storage device 11 may be a lithium ion battery or another secondary battery. The vehicle 10 may be a gasoline vehicle, a hybrid electric vehicle (HEV), a plug-in hybrid electric vehicle (PHEV), or an electric vehicle (EV).

The BMS 12 includes a storage unit (not shown) that collects and stores measurement data obtained by measuring a voltage, a current, a temperature, and the like of the energy storage device 11 at a predetermined sampling period, and history data (for example, a temperature history, a charge-discharge history, a state of charge (SOC) history, and the like) related to degradation of the energy storage device 11 based on these measurement data. The BMS 12 performs degradation estimation of the energy storage device 11 using the history data, and determines the reliability of the estimated value at the time of the degradation estimation. Various methods such as an internal resistance estimation method and an actual capacity estimation method can be used for the degradation estimation. The reliability may be determined each time the degradation is estimated based on the state of the energy storage device 11 and the degradation estimation method. The reliability may be expressed as, for example, “high”, “medium”, or “low”, may be expressed by five-stage numbers, or may be expressed by a numerical value within a range of 0 to 100%.

The BMS 12 includes a communication module (not shown) for transmitting measurement data, history data, an estimated value of degradation, and reliability to the server 50 via the roadside device 20 or directly to the server 50. Specifically, the BMS 12 may transmit the measurement data, the history data, the estimated value of degradation, and the reliability to the server 50 together with energy storage device data, an energy storage device ID, and a BMS ID using a mobile telephone network (for example, LTE [Long Term Evolution], 4G, 5GG, or the like), a wireless LAN (for example, WiFi or the like), or an intelligent transport system (ITS) radio.

The vehicle 10 includes an electronic control unit (ECU) (not shown). The ECU may collect the position data related to the use region of the vehicle 10 and transmit the collected position data to the server 50 together with the energy storage device ID and the ID of the BMS. The position data may be, for example, a travel history of the vehicle 10. As a result, it is possible to specify an area (region) in which the vehicle 10 (that is, the energy storage device 11) exists and a time (period) in which the vehicle 10 exists in the area.

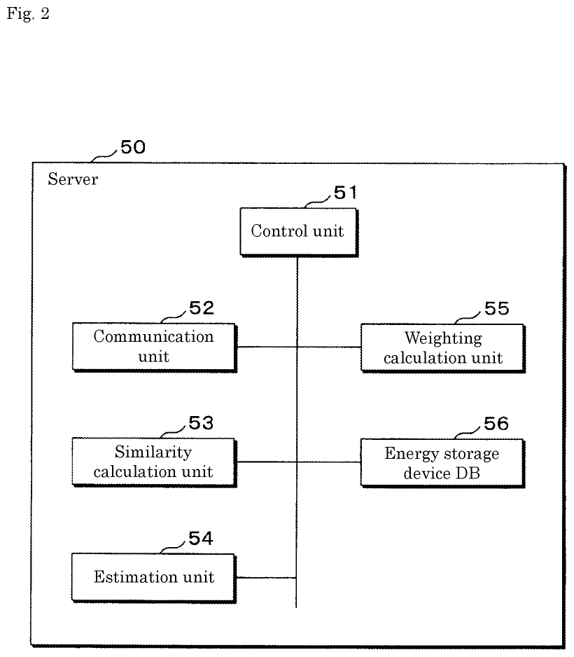

FIG. 2 is a diagram showing a configuration of the server 50. When the BMS 12 mounted on the vehicle 10 cannot accurately estimate the degradation index of the energy storage device 11 when estimating the degradation index of the energy storage device 11, the server 50 estimates the degradation index of the energy storage device 11 mounted on the vehicle 10 instead of the BMS 12. The server 50 includes a control unit 51, a communication unit 52, a similarity calculation unit 53, an estimation unit 54, a weighting calculation unit 55, and an energy storage device DB 56. Each unit of the server 50 may be distributed to a plurality of servers. The control unit 51 includes a central processing unit (CPU), a read only memory (ROM), a random access memory (RAM), and the like.

The communication unit 52 includes a communication module and can communicate with the BMS 12 via the roadside device 20 or directly with the BMS 12. The communication unit 52 has a function as an acquisition unit, and acquires measurement data, history data, estimated values of degradation, and reliabilities of the energy storage devices 11 from BMSs 12 mounted on a large number of vehicles 10. The communication unit 52 acquires position data of the vehicle 10 (that is, the energy storage device 11).

Various data (history data, degradation estimation data, use region data, and energy storage device data of energy storage devices 11) collected from the large number of vehicles 10 via the communication unit 52 is stored in the energy storage device DB 56 as big data. The communication unit 52 may acquire various data from the same vehicle 10 at different timings.

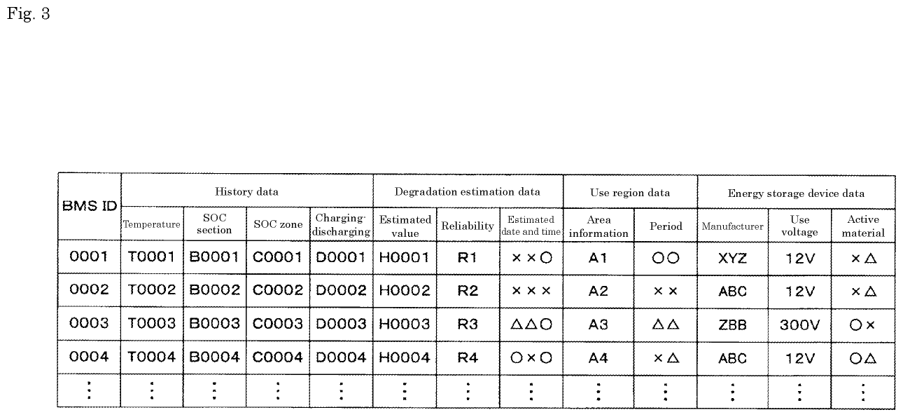

FIG. 3 is a diagram showing a configuration of the energy storage device DB 56. The energy storage device DB 56 may be provided in the server 50, or may be provided in another data server or the like accessible from the server 50. In the energy storage device DB 56, history data, degradation estimation data, use region data, and energy storage device data of the energy storage device 11 are associated with each BMS ID (which may be an energy storage device ID). The history data may include a temperature history, an SOC history (SOC section, SOC zone), a charge-discharge history, and the like. The history data may be time series data such as temperature, charging-discharging, and SOC, or may be statistical data calculated based on the time series data. The degradation estimation data may include an estimated value history of degradation, a reliability history of the estimated value, an estimated date and time history, and the like. The use region data may include an area information history in which the energy storage device 11 is used, a period for each area information, and the like. The energy storage device data may include a manufacturer of the energy storage device 11, a use voltage, an active material, and the like.

As shown in FIG. 3, for a BMS ID 0001, a temperature history data group T0001, an SOC section data group B0001, an SOC zone data group C0001, a charge-discharge history data group D0001, an estimated value history data group H0001, a reliability history data group R1, an estimated date and time data group XXO, an area information history data group A01, a period data group 00, manufacturer XYZ, a use voltage of 12 V, and an active material XΔ are recorded. The data group means an aggregate of data at each of a plurality of time points in the history data. The same applies to other BMS IDs. With the energy storage device DB 56, big data relating to degradation of a large number of energy storage devices 11 can be constructed.

The energy storage device DB 56 stores history data relating to degradation of each of the plurality of energy storage devices 11. The history data may be any data relating to degradation of the energy storage device 11, and includes, for example, a temperature history, a charge-discharge history, an SOC history, and the like. The history data may be time series data such as temperature, charging-discharging, and SOC, or may be statistical data calculated based on the time series data. For example, the temperature may be time-series data of the temperature, or may be statistical data representing the use time for each section by dividing the temperature into sections. The same applies to charging-discharging and SOC. The history data of the energy storage device 11 of the vehicle is collected from a plurality of vehicles, and the energy storage device DB 56 stores the collected history data in association with each vehicle (or battery management system (BMS)). History data collected at different timings from the same vehicle may be stored.

The communication unit 52 acquires history data relating to degradation of the energy storage device 11 as a degradation estimation target from the vehicle 10. The acquired history data is not already stored in the energy storage device DB 56, but is data used when the server 50 estimates the degradation index instead of the BMS 12. The vehicle 10 on which the energy storage device 11 as a degradation estimation target is mounted may use any power train (vehicle system).

The similarity calculation unit 53 calculates a similarity between the history data acquired from the vehicle 10 and the history data stored in the energy storage device DB 56. When the similarity is calculated, the history data to be compared may include at least one of a temperature history, a charge-discharge history, and an SOC history. When the temperature history, the charge-discharge history, or the SOC history can be compared, the similarity can be accurately calculated. For example, each pattern similar to the transition pattern of the temperature during use of the energy storage device 11 for which the degradation index is to be estimated, the charge-discharge pattern (charging period, charging cycle, discharging period, discharging cycle, pause period, or the like), or the transition pattern of the SOC may be searched from the history data stored in the energy storage device DB 56.

The estimation unit 54 estimates a degradation index based on the history data stored in the energy storage device DB 56 and similar to the history data acquired from the vehicle 10. For example, based on the transition of the SOC and the transition of the temperature from the time point t1 to the time point tn, the estimation unit 54 can estimate a decrease (degradation index) in the SOH from a difference in the SOH at the time point tn from the state of health (SOH) at the time point t1. The SOH estimated by the BMS 12 of the vehicle 10 may be used as the SOH at the time t1.

The communication unit 52 transmits the degradation index estimated by the estimation unit 54 to the vehicle 10.

With the above-described configuration, even when there is a situation where the degradation index of the energy storage device 11 mounted on the vehicle 10 cannot be accurately estimated, the degradation index estimated based on the history data similar to the history data reflecting the use state of the energy storage device 11 can be provided to the vehicle 10, and the degradation of the energy storage device 11 can be commonly estimated for diversified vehicle systems.

When the reliability of the degradation index estimated by the estimation unit 54 is higher than the reliability of the degradation index of the energy storage device 11 acquired from the vehicle 10, the communication unit 52 may transmit the degradation index estimated by the estimation unit 54 to the vehicle 10.

The reliability of the degradation index depends on the compatibility between the power train of the vehicle and the degradation estimation method for the energy storage device 11 of the vehicle 10. For example, the internal resistance estimation method is considered to have high accuracy in a case where the current at the time of cranking is large, but is considered not to have high accuracy in a case of the energy storage device 11 of a vehicle not equipped with an engine, in a case of an auxiliary battery, or the like. When the reliability of the degradation index estimated by the estimation unit 54 is higher than the reliability of the degradation index of the energy storage device 11 mounted on the vehicle 10, the degradation index estimated by the estimation unit 54 is transmitted to the vehicle 10, whereby a more accurate degradation index can be provided to the vehicle 10.

A similarity calculation method will be specifically described. Hereinafter, the temperature history, the SOC history, and the charge-discharge history will be described in this order.

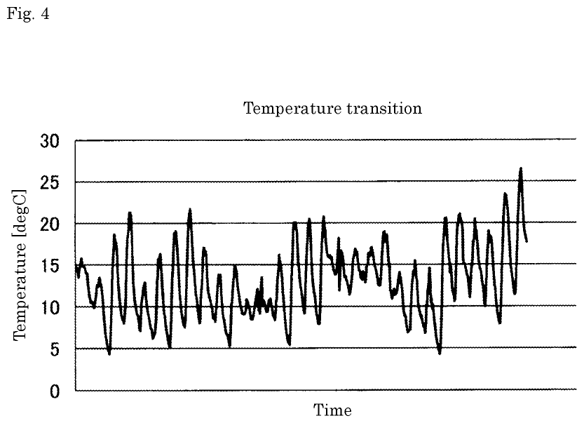

FIG. 4 is a diagram showing an example of time-series data of temperature. The horizontal axis represents time, and the vertical axis represents temperature. The temperature scale is an example, and other temperature transitions may be used. Various scales such as one day, three days, one week, one month, three months, six months, and one year may be used for the temperature transition. For example, in a case where the time scale is one month, the temperature transition as shown in FIG. 4 is obtained every month. In the case of the time-series data of the temperature of the energy storage device 11 as a degradation estimation target, the start point of the temperature transition may be the time point of the degradation estimation performed most recently by the BMS 12 or the time point of the degradation estimation when the reliability of the degradation estimation is relatively high. A time point at which the degradation index estimated by the BMS 12 is reliable to some extent may be set as a start point.

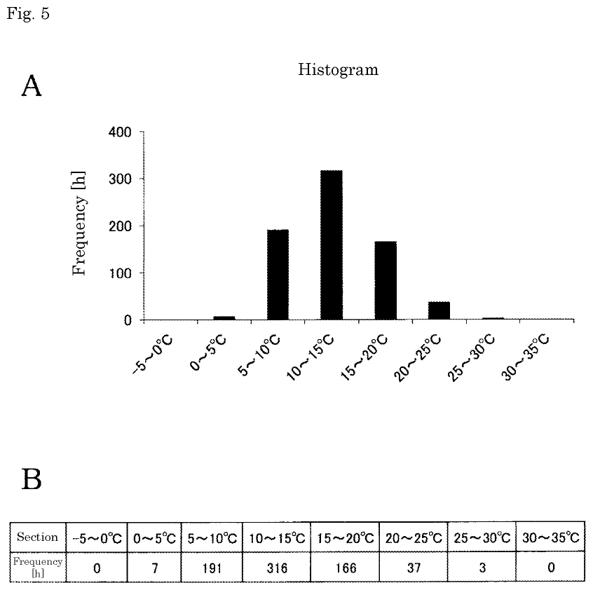

FIG. 5 is a diagram showing an example of a temperature histogram. The temperature histogram is a statistical value calculated based on the time-series data of the temperature, and is also a temperature history. The temperature histogram shows, for each temperature section of the energy storage device 11 as a degradation estimation target, a use time (frequency) in the section. In FIG. 5A, the temperature is divided into eight sections in the range of 5° C., and the use time in each section is represented as a histogram. FIG. 5B shows a feature vector calculated based on the temperature histogram. The feature vector has eight elements corresponding to eight sections, and each element is a frequency. When the feature vector is represented by V, the feature vector can be represented by V=(0, 7, 191, 316, 166, 37, 3, 0). The feature vector V may be normalized as described later.

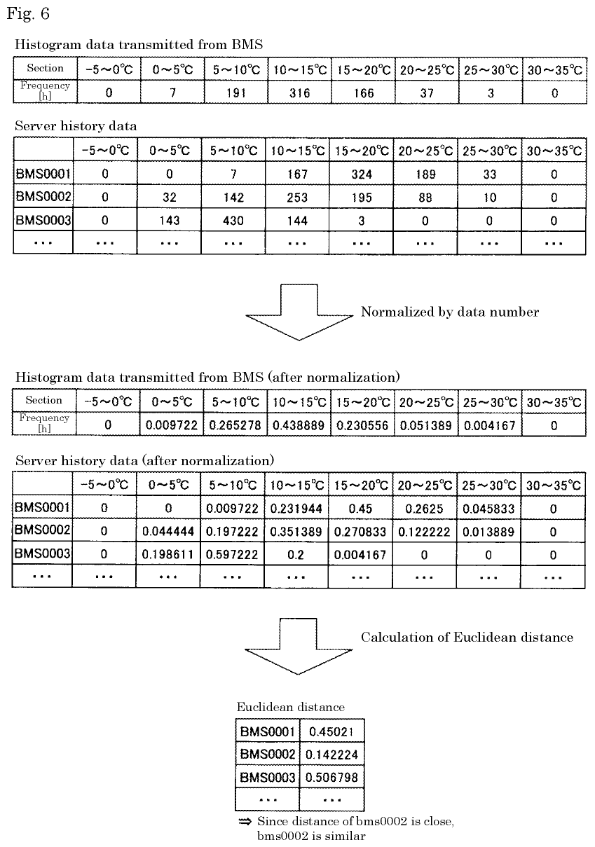

FIG. 6 is a diagram showing a calculation example of similarity using a temperature history. In the calculation of the similarity using the temperature history, the similarity between the temperature history acquired from the vehicle 10 and the temperature history stored in the energy storage device DB 56 is calculated. As shown in FIG. 5B, the feature vector V based on the time-series data of the temperature transmitted from the BMS 12 (vehicle 10) is V=(0, 7, 191, 316, 166, 37, 3, 0), and the normalized feature vector V is V′=(0, 0.009722, 0.265278, 0.438889, 0.230556, 0.051389, 0.004167, 0). On the other hand, normalized feature vectors Vs stored in the energy storage device DB 56 are Vs1=(0, 0, 0.009722, 0.231944, 0.45, 0.2625, 0.045833, 0), Vs2=(0, 0.044444, 0.197222, 0.351389, 0.270833, 0.122222, 0.013889, 0), Vs3=(0, 0.198611, 0.597222, 0.2, 0.004167, 0, 0, 0), . . . for each BMS.

The similarity calculation unit 53 calculates a similarity between the feature vector V′ based on the temperature history acquired from the vehicle 10 and each of the feature vectors Vs1, Vs2, Vs3, . . . based on the temperature history stored in the energy storage device DB 56. For example, a distance (for example, Euclidean distance) of each element of the feature vector may be used to calculate the similarity. It can be determined that the similarity increases as the distance decreases. In the example of FIG. 6, it is determined that the temperature history of the BMS00002 is the most similar.

Depending on the use state of the vehicle, the temperature of the energy storage device may be different, and the influence on the degradation of the energy storage device may also be different. By selecting the energy storage device 11 similar to the use temperature pattern of the energy storage device 11 as a degradation estimation target from among the BMSs (energy storage devices 11) stored in the energy storage device DB 56, the estimation accuracy of the degradation index can be enhanced.

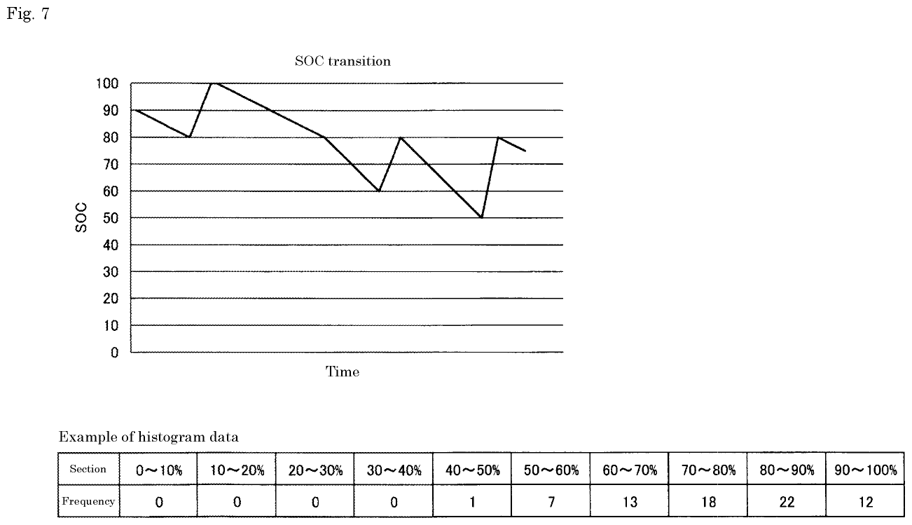

FIG. 7 is a diagram showing an example of the time-series data of the SOC. The horizontal axis represents time, and the vertical axis represents SOC. The SOC transition may use various scales such as one day, three days, one week, one month, three months, six months, and one year. For example, in a case where the time scale is one month, the SOC transition as shown in FIG. 7 is obtained every month. In the case of the time-series data of the SOC of the energy storage device 11 as a degradation estimation target, the start point of the SOC transition may be the time point of the degradation estimation performed most recently by the BMS 12 or the time point of the degradation estimation when the reliability of the degradation estimation is relatively high. A time point at which the degradation index estimated by the BMS 12 is reliable to some extent may be set as a start point.

The SOC section histogram is a statistical value calculated based on the time-series data of the SOC, and is also a SOC history. The SOC section histogram shows times (frequencies) during which the energy storage device 11 is used in the respective SOC sections by dividing the SOC of the energy storage device 11 as a degradation estimation target into predetermined sections (for example, a range of 10% or the like). In the case of FIG. 7, the feature vector calculated based on the SOC section histogram has 10 elements corresponding to 10 sections, and each element is a frequency. The calculation of the similarity can be performed similarly to the case of FIG. 6.

The transition of the SOC of the energy storage device may be different depending on the use state of the vehicle and the type of the vehicle (for example, HEV, EV, and the like), and it is considered that the influence on the degradation of the energy storage device is also different. By selecting the energy storage device 11 having a similar SOC transition pattern of the energy storage device 11 as a degradation estimation target from among the BMSs (energy storage devices 11) stored in the energy storage device DB 56, the estimation accuracy of the degradation index can be enhanced.

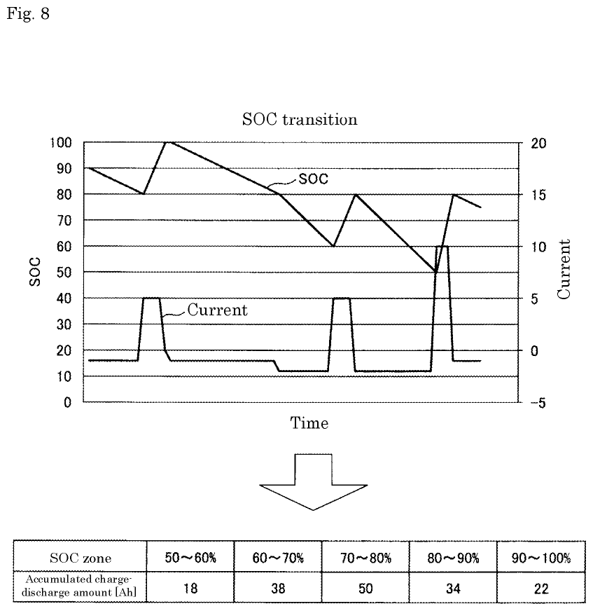

FIG. 8 is a diagram showing an example of time-series data of an SOC and a charge-discharge current. The horizontal axis represents time, and the vertical axis represents SOC and current. The SOC transition may use various scales such as one day, three days, one week, one month, three months, six months, and one year. For example, in a case where the time scale is one month, the SOC transition as shown in FIG. 8 is obtained every month. In the case of the time-series data of the SOC of the energy storage device 11 as a degradation estimation target, the start point of the SOC transition may be the time point of the degradation estimation performed most recently by the BMS 12 or the time point of the degradation estimation when the reliability of the degradation estimation is relatively high. A time point at which the degradation index estimated by the BMS 12 is reliable to some extent may be set as a start point.

The SOC zone histogram is a statistical value calculated based on the time-series data of the SOC, and is also a SOC history. The SOC zone histogram shows the accumulated charge-discharge amount (Ah) of the energy storage device 11 in predetermined SOC zones (for example, a range of 10% or the like) obtained by dividing the SOC of the energy storage device 11 as a degradation estimation target. In the case of FIG. 8, the feature vector calculated based on the SOC zone histogram has five elements corresponding to the five SOC zones, and each element is an accumulated charge-discharge amount. The calculation of the similarity can be performed similarly to the case of FIG. 6.

The transition of the SOC of the energy storage device may be different depending on the use state of the vehicle and the type of the vehicle (for example, HEV, EV, and the like), and it is considered that the influence on the degradation of the energy storage device is also different. By selecting the energy storage device 11 having a similar SOC transition pattern of the energy storage device 11 as a degradation estimation target from among the BMSs (energy storage devices 11) stored in the energy storage device DB 56, the estimation accuracy of the degradation index can be enhanced.

Although not shown, the charge-discharge history can also be expressed on various scales such as one day, three days, one week, one month, three months, six months, and one year. In the scale, the feature vector may be obtained using each element such as the number of times of charging, the charging period, the number of times of discharging, the discharging period, the number of times of pausing, and the pause period. The calculation of the similarity can be performed similarly to the case of FIG. 6.

With the above-described configuration, the energy storage device 11 having a similar charge-discharge pattern of the energy storage device 11 as a degradation estimation target can be selected from among the BMSs (energy storage devices 11) stored in the energy storage device DB 56.

When the similarity is calculated, the BMS (energy storage device 11) stored in the energy storage device DB 56 can be narrowed down and searched in advance under a predetermined condition. Hereinafter, the predetermined condition for searching will be described.

The similarity calculation unit 53 may calculate similarity between the history data acquired from the vehicle 10 and the history data of the energy storage device 11 having the use voltage in the same range as the use voltage of the energy storage device 11 mounted on the vehicle 10 among the plurality of energy storage devices 11 stored in the energy storage device DB 56. The use voltages in the same range may be divided into, for example, a low voltage such as 12 V and a high voltage such as several hundred V. By limiting to the use voltages in the same range, it is possible to suppress calculation of similarity between energy storage devices having different energy storage device characteristics depending on the level of the use voltage, progress of degradation, and the like. Accordingly, the estimation accuracy of the degradation index can be enhanced.

The similarity calculation unit 53 may calculate similarity between the history data acquired from the vehicle 10 and the history data of the energy storage device having entirely or partially the same active material as an active material of the energy storage device mounted on the vehicle 11 mounted on the vehicle 10 among the plurality of energy storage devices 11 stored in the energy storage device DB 56.

As the positive active material, for example, a material capable of occluding and releasing Li, such as a lithium transition metal oxide (Li1+aMeO₂, a≥1, Me: containing one or more transition metal elements such as Ni, Mn, and Co) such as lithium cobalt oxide, lithium nickel manganese cobalt oxide, or lithium nickel cobalt aluminum oxide, spinel type lithium manganate (LiMe₂O₄:Me is at least one metal element containing Mn), lithium iron phosphate, lithium iron manganese phosphate, or lithium vanadium phosphate, may be used. Two or more of these may be used in combination.

As the negative active material, for example, a material capable of occluding and releasing Li, such as graphite, hard carbon, soft carbon, metal Li, silicon monoxide, silicon or an alloy thereof, tin or an alloy thereof, lithium vanadate, tungsten oxide, titanium oxide, or niobium oxide, may be used. Two or more of these may be used in combination. By limiting to energy storage devices having entirely or partially the same active material, it is possible to suppress calculation of similarity between energy storage devices having different energy storage device characteristics depending on the difference in active material, progress of degradation, and the like. Accordingly, the estimation accuracy of the degradation index can be enhanced.

The similarity calculation unit 53 may calculate similarity between the history data acquired from the vehicle 10 and the history data of the energy storage device 11 of the same manufacturer as the operating voltage of the energy storage device 11 mounted on the vehicle 10 among the plurality of energy storage devices 11 stored in the energy storage device DB 56. By limiting to the energy storage devices of the same manufacturer, it is possible to suppress calculation of similarity between energy storage devices having different energy storage device characteristics depending on the difference in manufacturer, progress of degradation, and the like. Accordingly, the estimation accuracy of the degradation index can be enhanced.

The similarity calculation unit 53 may calculate similarity between the history data acquired from the vehicle 10 and the history data of the energy storage device 11 entirely or partially in the same use region as the use region of the energy storage device 11 mounted on the vehicle 10 among the plurality of energy storage devices 11 stored in the energy storage device DB 56. The use region may be, for example, 47 prefectures, may be divided into the Kanto region, the Kinki Region, and the like, or may be divided into urban areas, suburban areas, mountain areas, and the like. By limiting to energy storage devices of vehicles used entirely or partially in the same use region, it is possible to suppress calculation of similarity between energy storage devices having different energy storage device characteristics depending on the difference in use region, progress of degradation, and the like. Accordingly, the estimation accuracy of the degradation index can be enhanced.

The weighting in selecting the energy storage device 11 having the history data similar to the history data of the energy storage device 11 as a degradation estimation target from among the BMSs (energy storage devices 11) stored in the energy storage device DB 56 will be described.

The weighting calculation unit 55 may calculate the weighting based on the similarity calculated by the similarity calculation unit 53 and the reliability stored in the energy storage device DB 56.

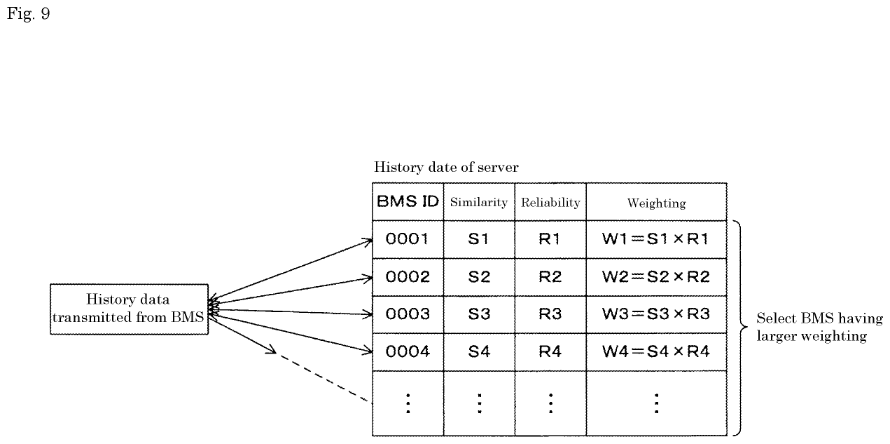

FIG. 9 is a diagram showing an example of weighting calculation. The weighting W may be calculated by, for example, W=S×R. S represents similarity, and R represents reliability of the degradation estimation data. In FIG. 9, the weighting W1 of the energy storage device 11 of the BMS ID 0001 is calculated by W1=S1×R1. S1 is the similarity calculated by the similarity calculation unit 53, and R1 is the reliability of the degradation estimation data of the BMS ID 0001. The same applies to other BMS IDs.

The control unit 51 has a function as a selection unit, and may select the energy storage device 11 from among the plurality of energy storage devices 11 based on the weighting calculated by the weighting calculation unit 55. The energy storage device 11 having the weighting W equal to or more than the predetermined threshold may be selected. Accordingly, the energy storage device 11 can be selected from among the plurality of energy storage devices 11 stored in the energy storage device DB 56 in consideration of both the similarity of the history data and the reliability of the degradation index. A plurality of energy storage devices 11 may be selected.

The estimation unit 54 may estimate the degradation index based on the history data of the selected energy storage device 11. As a result, the degradation index can be estimated in consideration of both the similarity of the history data and the reliability of the degradation index.

The calculation of the similarity and the calculation of the weighting may use machine learning such as a neural network.

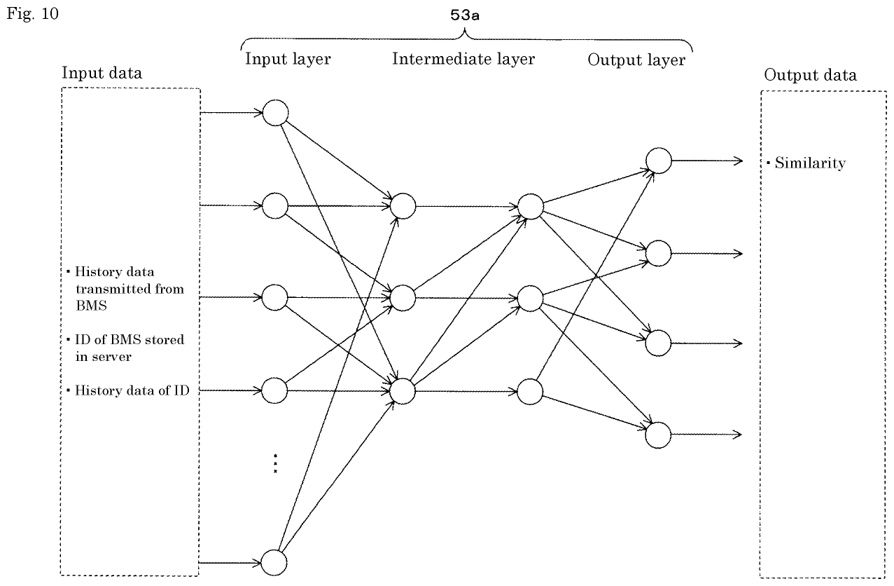

FIG. 10 is a diagram showing an example of a configuration of a learning model 53a. The learning model 53a is a neural network model including deep learning, and includes an input layer, an output layer, and a plurality of intermediate layers. Although two intermediate layers are shown in FIG. 10 for convenience, the number of intermediate layers may alternatively be three or more.

One or a plurality of nodes (neurons) exist in the input layer, the output layer, and the intermediate layer, and the nodes of each layer are combined with the nodes existing in the preceding and subsequent layers in one direction with a desired weight. A vector having the same number of components as the number of nodes of the input layer is provided as input data of the learning model 53a. The input data includes history data transmitted from the BMS 12 (history data acquired from the vehicle 10), an ID of the BMS stored in the server 50, history data of the ID (history data stored in the energy storage device DB 56), and the like. The output data includes the similarity of the history data of the ID. The number of IDs of the BMS included in the input data may be plural.

The output data can be vector format data having components of the same size as the number of nodes in the output layer (the size of the output layer). For example, the output node outputs the probability of each of the plurality of similarities. The plurality of similarities may be, for example, in a required range such as 90% to 100%, 80% to 90%, 70% to 80%, . . . , or a predetermined numerical value (95%, 90%, 85%, . . . ).

The learning model 53a can be configured by combining hardware such as a CPU (for example, a multi-processor in which a plurality of processor cores are mounted, or the like), graphics processing units (GPU), digital signal processors (DSP), and field-programmable gate arrays (FPGA), for example.

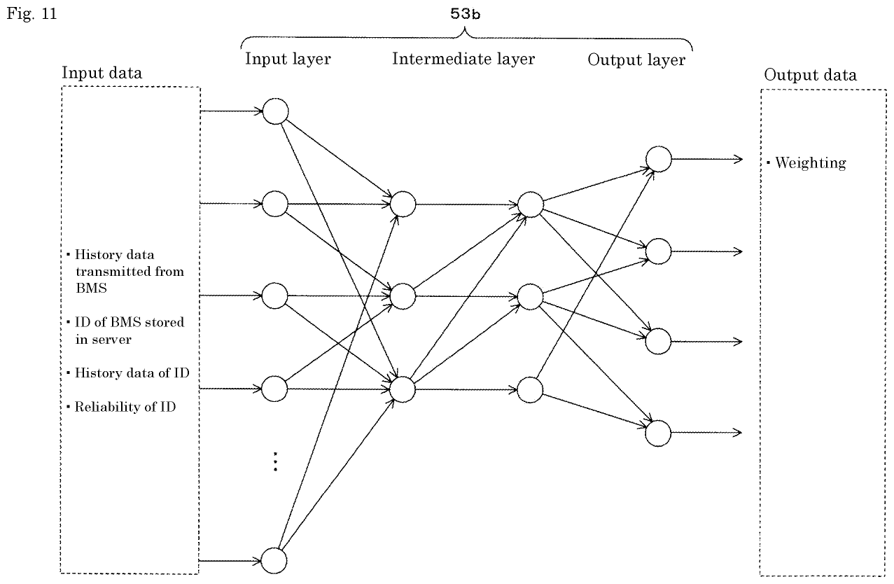

FIG. 11 is a diagram showing an example of a configuration of a learning model 53b. As shown in FIG. 11, the input data includes history data transmitted from the BMS 12 (history data acquired from the vehicle 10), an ID of the BMS stored in the server 50, history data of the ID, reliability of the history data of the ID (history data stored in the energy storage device DB 56), and the like. The output data includes weighting of the history data of the ID. The number of IDs of the BMS included in the input data may be plural.

The output data can be vector format data having components of the same size as the number of nodes in the output layer (the size of the output layer). For example, the output node outputs the probability of each of the plurality of reliabilities. The plurality of reliabilities may be, for example, in a required range such as 80% to 100%, 60% to 80%, 40% to 60%, . . . , or a predetermined numerical value (80%, 60%, 40%, . . . ).

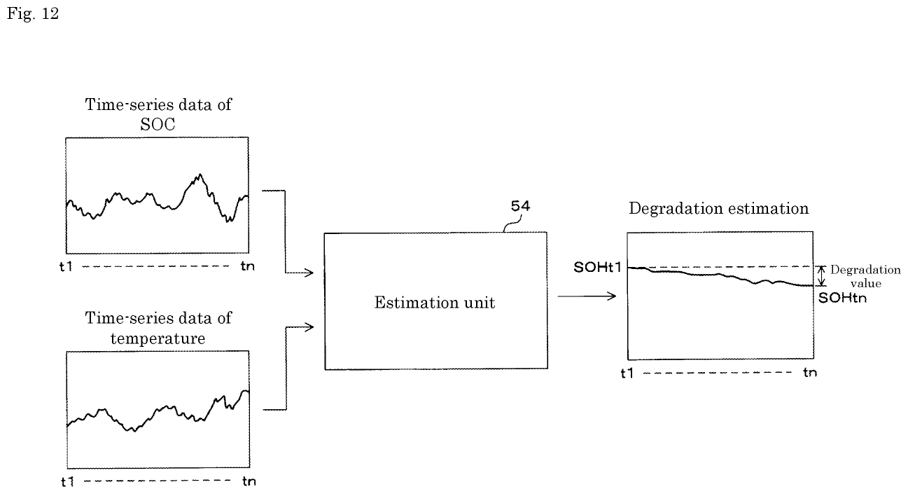

FIG. 12 is a diagram showing an example of estimation of a degradation index by the estimation unit 54. Upon acquiring history data (for example, SOC time-series data, time-series data of temperature, and the like) of the selected energy storage device 11 as input data, the estimation unit 54 estimates (calculates) a degradation value of the energy storage device 11. As shown in FIG. 12, the time-series data of the SOC indicates the SOC transition from the time point t1 to the time point tn, and the time-series data of the temperature indicates the temperature transition from the time point t1 to the time point tn.

The estimation unit 54 can estimate a decrease (degradation value and degradation index) in the SOH from the time point t1 to the time point tn based on the SOC transition and the temperature transition from the time point t1 to the time point tn. Assuming that SOH (also referred to as a health degree) at the time point t1 is SOHₜ₁ and SOH at the time point tn is SOHₜₙ, the degradation value is (SOHₜ−SOHₜₙ). That is, when the SOH at the time point t1 is known, the SOH at the time point tn can be obtained based on the degradation value.

The SOH estimated by the BMS 12 of the vehicle 10 may be used as the SOH at the time t1. Specifically, the time point t1 may be a time point of the most recent degradation estimation performed by the BMS 12 among a plurality of degradation estimations performed by the BMS 12 for the energy storage device 11 which is a degradation estimation target by the server 50, or may be a time point of the degradation estimation when the reliability of the degradation estimation is relatively high. The time point at which the degradation index estimated by the BMS 12 is reliable to some extent may be set as the time point t1.

The period from the time point t1 to the time point tn may be appropriately determined according to the history data of the selected energy storage device 11. In the example of FIG. 12, the temperature transition is input, but a required temperature (for example, the average temperature from the time point t1 to the time point tn) may be input instead of the time-series data of temperature.

The degradation value Qdeg of the energy storage device 11 after the elapse of the degradation estimation target period (for example, from the time point t1 to the time point tn) can be calculated by an expression of Qdeg=Qcnd+Qcur. Qcnd is a non-energization degradation value, and Qcur is a working electricity dependent degradation value. The non-energization degradation value Qcnd can be obtained by, for example, Qcnd=K1×√(t). The coefficient K1 is a function of the SOC and the temperature T. t is an elapsed time, for example, a time from the time point t1 to the time point tn. The energization degradation value Qcur can be obtained by, for example, Qcur=K2×√(t). The coefficient K2 is a function of the SOC and the temperature T. When SOH at the time point t1 is SOHₜ₁ and SOH at the time point tn is SOHₜₙ, SOH can be estimated by SOHₜₙ=SOHₜ₁−Qdeg. The coefficient K1 is a degradation coefficient, and a correspondence relationship between the coefficient K1 and the SOC and the temperature T may be obtained by calculation or may be stored in a table format. The SOC can be time-series data. The coefficient K2 is similar to the coefficient K1. The estimation unit 54 may use machine learning such as a neural network. The estimation unit 54 may estimate the degradation index by using an internal resistance estimation method or an actual capacity estimation method according to the history data of the selected energy storage device 11.

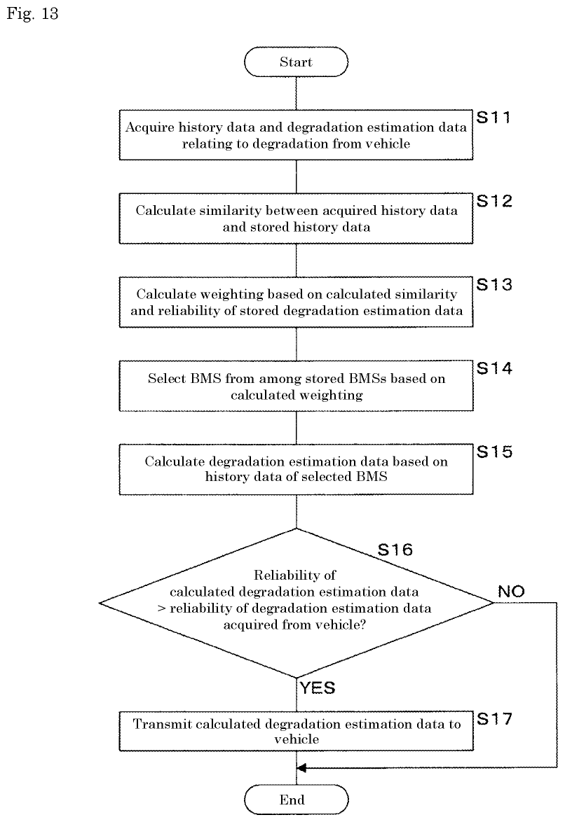

FIG. 13 is a flowchart showing a processing procedure of the server 50. The server 50 acquires history data and degradation estimation data relating to degradation of the energy storage device 11 from the vehicle 10 (S11). The history data may include a temperature history, a charge-discharge history, and an SOC history. The degradation estimation data may include an estimated value of degradation (degradation index) and reliability of the estimated value.

The server 50 calculates similarity between the acquired history data and the history data stored in the energy storage device DB 56 (S12), and calculates weighting based on the calculated similarity and reliability of the degradation estimation data stored in the energy storage device DB 56 (S13).

The server 50 selects the BMS (energy storage device 11) from among the BMSs (energy storage devices 11) stored in the energy storage device DB 56 based on the calculated weighting (S14), and calculates the degradation estimation data based on the history data of the selected BMS (energy storage device 11) (S15).

The server 50 determines whether or not the reliability of the calculated degradation estimation data is larger than the reliability of the degradation estimation data acquired from the vehicle 10 (S16). When the reliability is larger than the reliability of the acquired degradation estimation data (YES in S16), the server transmits the calculated degradation estimation data to the vehicle 10 (S17), and ends the processing. When the reliability of the calculated degradation estimation data is not larger than the reliability of the degradation estimation data acquired from the vehicle 10 (NO in S16), the server 50 ends the processing.

The server 50 may predict the future degradation estimation of each energy storage device 11 based on the calculated degradation estimation data, the transition tendency of the degradation estimation data, and the like, and transmit the predicted future degradation estimation to the vehicle 10 (BMS 12). By predicting the future degradation estimation, it is possible to predict the remaining period until the life of the energy storage device 11 mounted on the vehicle 10, and to replace the energy storage device 11 before the energy storage device 11 becomes unusable. When the plurality of energy storage devices 11 are mounted on the vehicle 10, only the energy storage device 11 which is approaching the end of its life can be replaced with a new one, and the life of the energy storage devices as a whole of the vehicle 10 can be extended.

The embodiment is illustrative in all respects and is not restrictive. The scope of the present invention is defined by the claims, and includes meanings equivalent to the claims and all modifications within the scope.

### DESCRIPTION OF REFERENCE SIGNS

1: communication network
10: vehicle
11: energy storage device
12: BMS
20: roadside device
50: server
51: control unit
52: communication unit
53: similarity calculation unit
53a, 53b: learning model
54: estimation unit
55: weighting calculation unit
56: energy storage device DB

1. An information processing apparatus comprising:
a storage unit that stores history data relating to degradation of each of a plurality of energy storage devices;
an acquisition unit that acquires history data relating to degradation of an energy storage device mounted on a vehicle;
a similarity calculation unit that calculates similarity between the acquired history data and the stored history data;
an estimation unit that estimates a degradation index based on the stored history data which is similar to the acquired history data; and
a transmission unit that transmits the estimated degradation index to the vehicle.

2. The information processing apparatus according to claim 1,
wherein the acquisition unit acquires reliability of a degradation index of the energy storage device mounted on the vehicle, and
wherein the transmission unit transmits, when reliability of the degradation index estimated by the estimation unit is higher than the reliability acquired by the acquisition unit, the estimated degradation index to the vehicle.

3. The information processing apparatus according to claim 1 or 2,
wherein the storage unit stores reliability of a degradation index of each of the plurality of energy storage devices,
wherein the information processing apparatus includes:
a weighting calculation unit that calculates a weighting based on the calculated similarity and the stored reliability; and
a selection unit that selects an energy storage device from among the plurality of energy storage devices based on the calculated weighting, and
wherein the estimation unit estimates a degradation index based on history data of the selected energy storage device.

4. The information processing apparatus according to any one of claims 1 to 3,
wherein the similarity calculation unit calculates similarity between the acquired history data and history data of an energy storage device, which has a use voltage in the same range as a use voltage of the energy storage device mounted on the vehicle, among the plurality of energy storage devices stored in the storage unit.

5. The information processing apparatus according to any one of claims 1 to 3,
wherein the similarity calculation unit calculates similarity between the acquired history data and history data of an energy storage device, which has entirely or partially the same active material as an active material of the energy storage device mounted on the vehicle, among the plurality of energy storage devices stored in the storage unit.

6. The information processing apparatus according to any one of claims 1 to 3,
wherein the similarity calculation unit calculates similarity between the acquired history data and history data of an energy storage device of the same manufacturer as the energy storage device mounted on the vehicle among the plurality of energy storage devices stored in the storage unit.

7. The information processing apparatus according to any one of claims 1 to 3,
wherein the storage unit stores position data relating to a use region of each of the plurality of energy storage devices,
wherein the acquisition unit acquires position data related to a use region of the vehicle, and
wherein the similarity calculation unit calculates similarity between the acquired history data and history data of an energy storage device entirely or partially in the same use region as a use region of the energy storage device mounted on the vehicle among the plurality of energy storage devices stored in the storage unit.

8. The information processing apparatus according to any one of claims 1 to 7,
wherein the history data includes a use time in each of temperature sections for each of the temperature sections of the energy storage device.

9. The information processing apparatus according to any one of claims 1 to 8,
wherein the history data includes a use time in each of SOC sections for each of the SOC sections of the energy storage device.

10. The information processing apparatus according to any one of claims 1 to 9,
wherein the history data includes an accumulated charge-discharge amount in each of SOC sections for each of the SOC sections of the energy storage device.

11. The information processing apparatus according to any one of claims 1 to 10,
wherein the estimation unit predicts future degradation estimation of the energy storage device based on the estimated degradation index or transition of the degradation index, and
wherein the transmission unit transmits the prediction of the degradation estimation to the vehicle.

12. An information processing method comprising:
storing history data relating to degradation of each of a plurality of energy storage devices in a storage unit;
acquiring history data relating to degradation of an energy storage device mounted on a vehicle;
calculating similarity between the acquired history data and the stored history data;
estimating a degradation index based on the stored history data which is similar to the acquired history data; and
transmitting the estimated degradation index to the vehicle.
